(19) United States
(12) Patent Application Publication
(10) Pub. No.: US 2002/0108711 A1
(43) Pub. Date: Aug. 15, 2002

(54) Gas distribution apparatus of semiconductor equipment

(75) Inventor: Yong-Kil Kim, Kyonggi-do (KR)

Correspondence Address: MARGER JOHNSON & McCOLLOM, P.C., 1030 S.W. Morrison Street, Portland, OR, 97205, US

(73) Assignee: Samsung Electronics Co., Ltd., Suwon-city (KR)

(21) Appl. No.: 10/072,443

(22) Filed: Feb. 5, 2002

(30) Foreign Application Priority Data
Feb. 9, 2001 (KR) 2001-6303

(51) Int. Cl. C23F 1/00; C23C 16/00

(52) U.S. Cl. 156/345.33; 118/715

(57) ABSTRACT

The invention relates to a gas distribution apparatus of semiconductor equipment in which parts are assembled in a simple way in a chamber to thereby improve job efficiency in assembling and disassembling operations and prevent gas leakage outside. The apparatus assembled to supply gas into a chamber for a plasma etching process comprises: a body having a plurality of gas inducing inlets on a downward grooved side of its plate; and an injection plate screwed with the bottom surface of the body, the injection plate having small and large diameters of ring-shaped grooves on its upper surface to connect the gas inducing inlets, the grooves having injection holes formed at a predetermined interval for downward penetration, so as to completely prevent gas leakage outside.

### BACKGROUND OF THE INVENTION

1. Field of the Invention

The present invention relates to a gas distribution apparatus of semiconductor equipment in which parts are assembled in a simple way in a chamber to thereby improve job efficiency when assembling and disassembling the chamber and prevent gas leakage outside.

2. Description of the Related Art

In general, there is provided a gas distribution apparatus used for uniformly distributing gas into a chamber as a plasma etching device in semiconductor manufacturing equipment.

The gas distribution apparatus of the etching device as such has been constructed in a great number of structures for performing the most important role to uniformly diffuse gas and to prevent gas leakage outside at the same time.

In this regard, there have been a variety of conventional methods disclosed in Korea utility model No. 20-169709 and in U.S. Pat. No. 5,685,914. Particularly, according to utility model No. 20-169709, gas is directly introduced from one end of a cover body to simplify that design of a gas inducing pipe.

However, there are problems in the conventional gas distribution apparatus in that, as the apparatus is a very complicated structure defining an internal gas route with a great number of parts has been difficult to prevent gas leakage.

FIG. 1 illustrates a gas distribution apparatus of a design commonly used in a plasma etching device, largely comprising: body 100, ring plate 200 and cover plate 300. In other words, the conventional gas distribution apparatus is constructed with: a pan-shaped body 100 with a recessed bottom surface; a ring plate 200 to cover ring-shaped grooves 120 formed in the recessed bottom surface 110 of the body 100; and a cover plate 300 to press down and cover the ring plate 200. The ring plate 200 is inserted along the surface of the body 100, which is finally screwed with the cover plate 300.

Particularly, ring shaped groove 120 includes small diameter grooves 121 formed at the internal periphery concentric and large diameter grooves 122 formed at the external periphery. Additionally, two O-rings 123 are respectively provided along the internal periphery of each of grooves 121, 122. Then, small and large diameter ring plates 210, 220 are respectively pressed onto the small and large diameter grooves 121, 122.

Gas injection inlets 211, 221 protrude upwardly from ring plates 200 and 210, respectively. A plurality of injection holes 130 extend downwardly at a predetermined interval in the ring-shaped grooves 120 of the body 100. In addition, through-holes 310, 320 are formed in the cover plate 300 for penetration of the gas injection inlets 211, 221 that protrude upwardly from the ring plate 200.

On the other hand, cooling water inlet and discharge holes 330, 340 are respectively formed across from the though-holes 310, 320 into which the gas injection inlets 211, 221 of the cover plate 300 are inserted. Water inlet and discharge holes 330, 340 are connected by a cooling water path (not shown).

First of all, the ring plate 200 is placed over the grooves 120 of the surface 110, thereby making a seal with O-rings 123. Then, the cover plate 300 is placed over the ring plate 200 and a plurality of screws 400 are used for fastening the cover plate 300 to surface 110. As a result, all the parts have been assembled into the tightly assembled structure as shown in FIG. 2.

However, in the aforementioned structure, cover plate 300 is fastened outside the chamber. In order to ensure tightness, about 30 screws 400 have been utilized to fasten the body 100 and the cover plate 300. If any of the screws 400 are not properly tightened compression force of the ring plate 200 may decrease and bring about a danger of leaking of gas outside.

In addition, there are problems such as inconvenience and loss of operational time because of disrupted operations and unnecessary cleanings in case of incidents of gas leakage, that is, stopping operation of the apparatus, disassembling, cleaning and reassembling some parts and re-starting operation of it.

In addition, as the O-rings 123 and screws 400 are generally abraded more rapidly with frequent disassembling and assembling processes, there is an additional economic disadvantage in increased maintenance and repair cost.

### SUMMARY OF THE INVENTION

It is an object of the present invention to solve the aforementioned problems and improve job efficiency in disassembling and assembling processes through a reduction in the number of parts.

It is another object of the present invention to improve operational reliability of a gas distribution apparatus of semiconductor equipment by reducing the number of fastened parts to improve air-tightness.

In order to accomplish the aforementioned objects of the present invention, there is provided a gas distribution apparatus of semiconductor equipment to supply gas into a chamber for a plasma etching process, the apparatus comprising:

a body having a plurality of gas inducing inlets and a cooling means on the downward grooved surface of its bottom plate; and

an injection plate screwed to the body, the injection plate having small and large diameter ring-shaped grooves on its upper surface to connect the gas inducing inlets, the grooves having downwardly extending injection holes formed at predetermined intervals.

### BRIEF DESCRIPTION OF THE DRAWINGS

For fuller understanding of the nature and object of the invention, reference should be made to the following detailed description taken in conjunction with the accompanying drawings in which:

FIG. 1 is a cross-sectional view for illustrating a conventional gas distribution apparatus;

FIG. 2 is a cross-sectional view for illustrating an assembled conventional gas distribution apparatus shown in FIG. 1;

FIG. 3 is a cross-sectional view for illustrating an analyzed state of a gas distribution apparatus in accordance with the present invention; and

FIG. 4 is a cross-sectional view for illustrating an assembled gas distribution apparatus in accordance with the present invention.

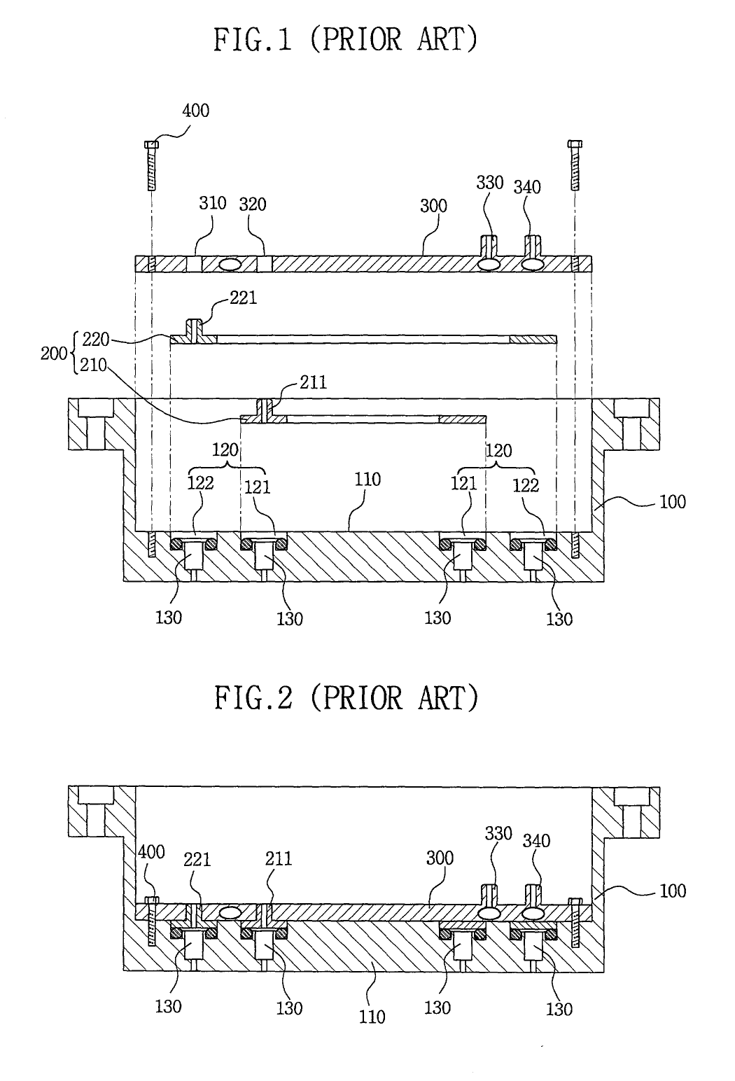

### DETAILED DESCRIPTION OF THE INVENTION

Object and characteristics of the present invention will become apparent from the following detailed description of a preferred embodiment with reference to the accompanying drawings.

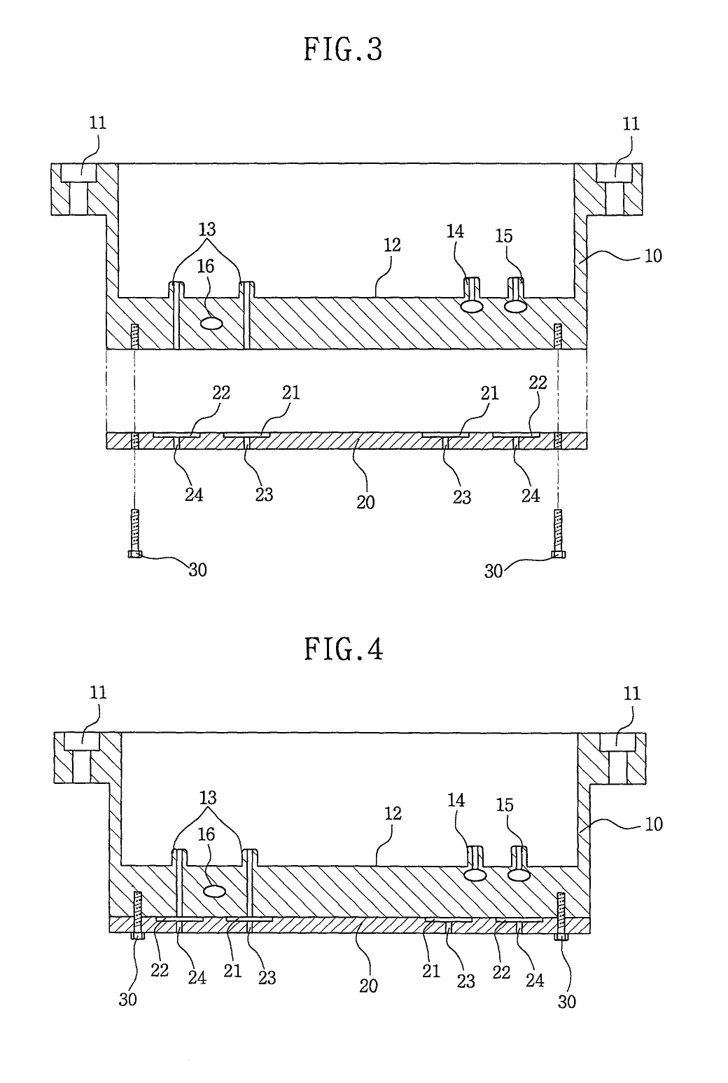

FIG. 3 illustrates a gas distribution apparatus of the present invention, including a body 10 and an injection plate 20.

The body 10 is formed in a pan shape with its downward grooved plate. Like in the conventional structure, a plurality of vertically penetrated, fastening holes 11 are formed at the external peripheral flange extending laterally from the top of the body 10 for a tight fastening with the chamber.

At the internal side of the downward grooved bottom part 12 of the body 10, a plurality of gas inducing inlets 13, just like those formed at the ring plate of the conventional apparatus, protrude upwardly with various diameters at different distances from the center of the plate surface. The internal diameters of those gas inducing inlets 13 extend downwardly through the body 10.

In the present invention, the gas inducing inlets 13 are integrally formed in the body 10, as opposed to those formed at separate ring plates in the prior art.

On the other hand, cooling passages are formed at odd angles from the positions of the gas inducing inlets 13 for admitting, discharging, or circulating cooling water through the body 10. The cooling means includes an injecting hole 14, a discharging hole 15 upwardly protruding from the surface 12 of the body 10 and a cooling water path 16 connecting the injecting and discharging holes 14, 15.

In addition, a flat injection plate 20 is fastened to the body 10 with plurality of screws 30. The injection plate 20 is formed in the same size of a diameter as the bottom part of the body, with concentric circular grooves 21, 22 having different diameters on its upper side, which is then to be attached to the body 10. The grooves 21, 22 are vertically connected with the gas inducing inlets 13, and injection holes 23, 24 are respectively formed at the grooves 21, 22 for vertical penetration through the injection plate 20. The injection holes 23, 24 are formed at predetermined intervals along the grooves 21, 22. Particularly, it is preferable that the bottom part of the injection hole 24 formed at the groove 22 having a larger diameter should not be bigger than the diameter of a wafer to be processed in the chamber.

In the gas distribution apparatus of the present invention thus constructed, as described in FIG. 4, the injection plate 20 is simply fastened to the lower surface of the body 10 with a plurality of screws 30. The external periphery outside at the upper part of the body 10 is firmly fastened to the chamber, and nozzles of respective gas supply hoses are coupled with the gas inducing inlets upwardly protruded from the bottom surface 12 of the body. The cooling hoses are respectively fastened to the cooling water inlet and discharge holes 14, 15.

The gas distribution apparatus assembled in the aforementioned manners supplies gas through the gas inducing inlet 13 to the grooves 21, 22 formed at the surface of the injection plate 20 with different sizes of diameters and, then, injects the gas into the chamber through the injection holes 23, 24 formed at the grooves 21, 22.

Gas is supplied through the one injection hole 23 formed in a smaller size of a diameter to the internal surface of the wafer induced in the chamber and through the other injection hole 24 formed in a larger size of a diameter to the external surface of the wafer, so that gas can be uniformly supplied to all the surfaces of the wafer. The injection plate 20 is placed inside the chamber, so that the gas leakage can be completely prevented even if the body 10 and the injection plate 20 are not firmly fastened.

In other words, in the prior art, a ring plate and a cover plate are fastened to the bottom surface down from the body, an external part of the chamber. If the cover plate is not tightly fastened with the body, there has been a problem of gas leakage outside. However, according to the gas distribution apparatus of the present invention, the injection plate 20 is placed inside the chamber to supply all the gas into the chamber, including even leaking gas, if any, due to the loose fastening with the body.

In the prior art, a large number of screws have been utilized to fasten the body and cover plate to prevent gas leakage and maintain air tightness. In this invention, a small number of screws are used to fasten the body 10 and the injection plate 20, achieving a good seal and a more convenient fastening method.

In addition, in order to prevent gas leakage, without using a number of parts like a pair of ring plates, O-rings or cover plates in the prior art, an injection plate 20 is simply fastened to the body 10 with screws in the present invention, so as to simplify the assembling and disassembling processes as well as significantly reduce the general manufacturing cost relating to the gas distribution apparatus.

As described above, there are advantages in the gas distribution apparatus of semiconductor equipment of the present invention in that the apparatus is made with a smaller number of parts in a more simplified structure at a lower manufacturing cost to completely prohibit gas leakage, thereby preventing a possibility of external pollution, performing stable operations of the apparatus to improve operational efficiency of the equipment, and more particularly, simplifying disassembling and assembling processes and increasing tenacity of the parts to cut down maintenance and repair cost.

What is claimed is:

1. A gas distribution apparatus for supplying gas into a semiconductor wafer processing chamber, the apparatus comprising:
a body having a bottom wall and a plurality of gas inlets extending through the bottom wall; and
an injection plate to be screwed with the bottom part of the body, the injection plate having small and large diameters of ring-shaped grooves on its upper surface to connect the gas inducing inlets, the grooves having injection holes formed at a predetermined interval for downward penetration.

2. The apparatus, as defined in claim 1, wherein the gas inducing inlets are formed at different distances from the center of the bottom part of the body.

3. The apparatus, as defined in claim 1, wherein the gas inducing inlets upwardly protrude from the body.

4. The apparatus, as defined in claim 1, wherein the external periphery of the upper portion body is fastened to the chamber.

5. The apparatus, as defined in claim 1, wherein the body includes the gas inducing inlets with a vertically extended diameter for downward penetration.

6. The apparatus, as defined in claim 1, wherein the injection plate is fastened with the bottom part of its external periphery to the bottom surface of the body with a plurality of screws.

7. A gas distribution apparatus of semiconductor equipment to supply gas into a chamber for a plasma etching process, the apparatus comprising:
a body having a plurality of gas inducing inlets and cooling water means on a downward grooved side of its plate; and
an injection plate attached to the bottom surface of the body, the injection plate having small and large diameter ring-shaped grooves on its upper surface to connect the gas inducing inlets, the grooves having injection holes formed at a predetermined interval for downward penetration.

8. The apparatus, as defined in claim 7, wherein the gas inducing inlets are formed at different diameters from the center of the bottom part of the body.

9. The apparatus, as defined in claim 7, wherein the gas inducing inlets are upward protruded from the body.

10. The apparatus, as defined in claim 7, wherein the external periphery of the upper portion body is fastened to the chamber.

11. The apparatus, as defined in claim 7, wherein the body has the gas inducing inlets with a vertically extended diameter for downward penetration.

12. The apparatus, as defined in claim 7, wherein the injection plate is fastened with the bottom part of its external periphery to the bottom surface of the body with a plurality of screws.

13. The apparatus, as defined in claim 7, wherein the cooling means includes injecting and discharging holes for inducing and discharging cooling water and a cooling water path connecting the injecting and discharging holes for circulating cooling water in the body.

14. The apparatus, as defined in claim 13, wherein the injecting and discharging holes are upwardly protruded from the bottom part of the body.
